(19) United States
(12) Patent Application Publication
(10) Pub. No.: US 2026/0006720 A1
(43) Pub. Date: Jan. 1, 2026

(54) WIRING CIRCUIT BOARD

(71) Applicant: NITTO DENKO CORPORATION, Osaka (JP)

(72) Inventors: Yusaku TAMAKI, Osaka (JP); Shusaku SHIBATA, Osaka (JP); Makiko HIRATA, Osaka (JP)

(73) Assignee: NITTO DENKO CORPORATION, Osaka (JP)

(21) Appl. No.: 19/247,942

(22) Filed: Jun. 24, 2025

(30) Foreign Application Priority Data
Jun. 28, 2024 (JP) 2024-105499

(51) Int. Cl. H05K 1/05; H05K 1/09

(52) U.S. Cl. CPC H05K 1/05; H05K 1/09; H05K 2201/09236; H05K 2201/09381

(57) ABSTRACT

The wiring circuit board includes a metal supporting layer, a terminal, and a first insulating layer. The first insulating layer has a first end edge on one side in a first direction and a second end edge on the other side in the first direction. The terminal has a third end edge on one side in the first direction and a fourth end edge on the other side in the first direction. The metal supporting layer has a fifth end edge on one side in the first direction and a sixth end edge on the other side in the first direction. The third end edge and the fifth end edge are disposed between the first end edge and the second end edge. A total sum of a distance between the first end edge and the fifth end edge and a distance is 15 μm or more.

### CROSS REFERENCE TO RELATED APPLICATION

The present application claims priority to Japanese Patent Application No. 2024-105499, filed on Jun. 28, 2024, the contents of which are herein incorporated by reference in its entirety.

### TECHNICAL FIELD

The present invention relates to a wiring circuit board.

### BACKGROUND ART

Conventionally, there has been known a wiring circuit board including a metal supporting layer, a conductive pattern disposed on one side of the metal supporting layer in the thickness direction, and a base insulating layer disposed between the metal supporting layer and the conductive pattern (ref: for example, Patent Document 1 below).

### CITATION LIST

### Patent Document

Patent Document 1: Japanese Unexamined Patent Publication No. 2023-171201

### SUMMARY OF THE INVENTION

### Problem to be Solved by the Invention

In the wiring circuit board as described in Patent Document 1, there is studied that the distance between the end edge of the base insulating layer and the terminal is shortened in order to reduce the size of the wiring circuit board.

In this regard, when the distance between the end edge of the base insulating layer and the terminal is shortened, if the solder on the terminal melts and flows toward the end edge of the base insulating layer, the flowing solder may cross the end edge of the base insulating layer and finally reach the metal supporting layer.

When the flowing solder reaches the metal supporting layer, a short circuit may occur between the terminal and the metal supporting layer.

The present invention provides a wiring circuit board capable of suppressing the short circuit between the terminal and the metal supporting layer while achieving reduction in the size of the wiring circuit board.

### Means for Solving the Problem

The present invention [1] includes a wiring circuit board including a metal supporting layer; a terminal disposed on one side of the metal supporting layer in a thickness direction of the metal supporting layer; and a first insulating layer disposed between the metal supporting layer and the terminal in the thickness direction, the first insulating layer extending in a first direction orthogonal to the thickness direction, and in the first direction, having a first end edge and a second end edge disposed on a side opposite to the first end edge, the terminal having a third end edge disposed between the first end edge and the second end edge in the first direction, and a fourth end edge disposed between the third end edge and the second end edge in the first direction, the metal supporting layer having a fifth end edge disposed between the first end edge and the second end edge in the first direction, and a sixth end edge disposed on the side opposite to the first end edge with respect to the fifth end edge in the first direction, in which a total sum of a distance between the first end edge and the third end edge and a distance between the first end edge and the fifth end edge is 15 μm or more.

According to this configuration, the total sum of the distance between the first end edge and the third end edge and the distance between the first end edge and the fifth end edge of the metal supporting layer is 15 μm or more.

Therefore, even when the first end edge of the first insulating layer is disposed close to the terminal, the distance from the terminal to the metal supporting layer can be secured.

Therefore, even though the solder on the terminal flows toward the first end edge, it is possible to suppress a short circuit between the terminal and the metal supporting layer due to the flowing solder.

As a result, the wiring circuit board can suppress a short circuit between the terminal and the metal supporting layer while achieving reduction in the size of the wiring circuit board.

The present invention [2] includes the wiring circuit board described in [1], in which the distance between the first end edge and the third end edge is 200 μm or less.

According to this configuration, it is possible to achieve reduction in the size of the wiring circuit board.

The present invention [3] includes the wiring circuit board described in [1] or [2], in which the distance between the first end edge and the fifth end edge is longer than the distance between the first end edge and the third end edge.

According to this configuration, the first end edge of the first insulating layer can be brought closer to the terminal. Therefore, it is possible to achieve further reduction in the size of the wiring circuit board.

The present invention [4] includes the wiring circuit board described in any one of the above-described [1] to [3], further including a second insulating layer disposed on one side of the first insulating layer in the thickness direction, in which a portion of the second insulating layer is disposed between the first end edge and the third end edge in the first direction.

According to this configuration, the second insulating layer between the first end edge and the third end edge can suppress flowing of the solder on the terminal toward the first end edge.

The present invention [5] includes the wiring circuit board described in [4], in which the second insulating layer covers the third end edge.

According to this configuration, the second insulating layer can further suppress flowing of the solder on the terminal toward the first end edge.

The present invention [6] includes the wiring circuit board described in any one of the above-described [1] to [5], in which the metal supporting layer has one end portion and the other end portion in the first direction, and has a recessed portion recessed from the one end portion toward the other end portion in the first direction, the recessed portion overlaps the third end edge in the thickness direction, and the fifth end edge is a bottom of the recessed portion.

The present invention [7] includes the wiring circuit board described in any one of the above-described [1] to [6], further including a wire disposed between the second end edge and the fourth end edge and connected to the terminal.

### Effects of the Invention

According to the wiring circuit board of the present invention, it is possible to suppress a short circuit between the terminal and the metal supporting layer while achieving reduction in the size of the wiring circuit board.

### BRIEF DESCRIPTION OF THE DRAWINGS

FIG. 1 is a plan view of an embodiment of a wiring circuit board of the present invention.

FIG. 2 is a cross sectional view taken along line A-A of the wiring circuit board shown in FIG. 1.

FIG. 3 is a plan view of the wiring circuit board of a modification (1).

FIG. 4 is a plan view of the wiring circuit board of a modification (2).

FIGS. 5A and 5B are plan views of the wiring circuit board of a modification (3).

FIGS. 6A and 6B are plan views of the wiring circuit board of a modification (4).

FIG. 7A is a plan view of the wiring circuit board of a modification (5), and FIG. 7B is a cross sectional view taken along line B-B of the wiring circuit board shown in FIG. 7A.

FIG. 8 is a plan view of the wiring circuit board of a modification (6).

### DESCRIPTION OF THE EMBODIMENTS

### 1. Wiring Circuit Board

As shown in FIG. 1, a wiring circuit board 1 extends in a first direction and a second direction. The second direction is orthogonal to the first direction. The wiring circuit board 1 has a predetermined width W0 in the first direction and extends longer than the width W0 in the second direction. The second direction is a direction in which a plurality of terminals 41A, 41B are aligned. The terminals 41A, 41B will be described later.

The width W0 of the wiring circuit board 1 may be the same as or different from a width W11 of a first insulating layer 3 to be described later. The width W0 (length of the first direction) of the wiring circuit board 1 is, for example, 200 μm to 1800 μm, preferably 300 μm to 1600 μm. Specifically, the width W0 of the wiring circuit board 1 is a width of a portion in which the terminals 41A, 41B are disposed, of the wiring circuit board 1.

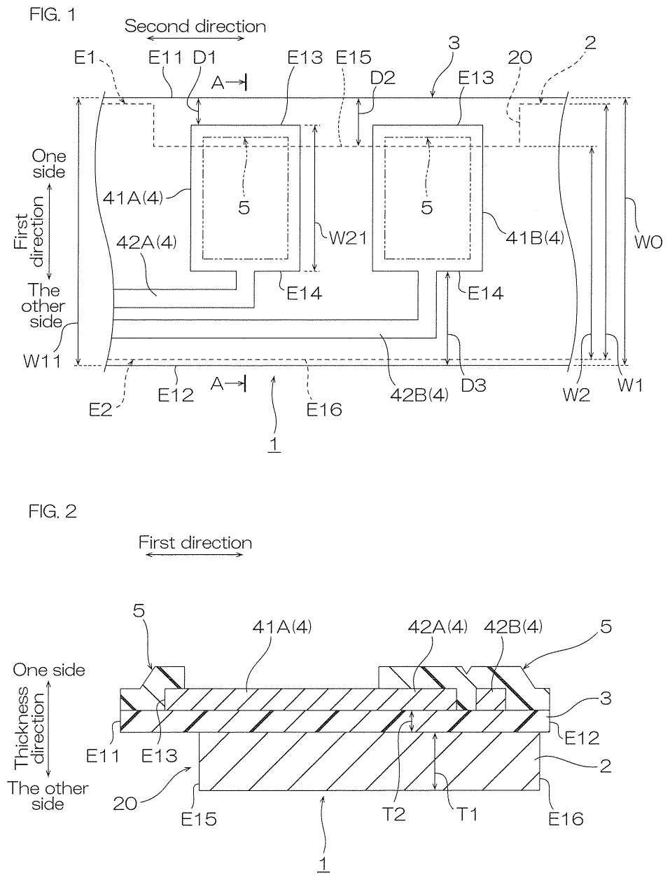

As shown in FIG. 2, the wiring circuit board 1 includes a metal supporting layer 2, the first insulating layer 3, a circuit pattern 4, and a second insulating layer 5.

### (1) Metal Supporting Layer

The metal supporting layer 2 supports the first insulating layer 3, the circuit pattern 4, and the second insulating layer 5. Examples of the material of the metal supporting layer 2 include stainless steel and copper alloy. The metal support layer 2 may have a plurality of layers made of metals different from each other.

The metal supporting layer 2 has a thickness T1 of, for example, 10 μm to 250 μm, preferably 20 μm to 200 μm.

As shown in FIG. 1, the metal supporting layer 2 extends in the first direction and the second direction. The metal supporting layer 2 has a predetermined width W1 in the first direction and extends in the second direction. The metal supporting layer 2 has one end portion E1 and the other end portion E2 in the first direction. The other end portion E2 is an end portion on the side opposite to the one end portion E1 in the first direction. The other end portion E2 is disposed away from the one end portion E1 in the first direction. The metal supporting layer 2 has a recessed portion 20.

The recessed portion 20 is disposed at the one end portion E1 of the metal supporting layer 2 in the first direction. The recessed portion 20 is recessed from the one end portion E1 toward the other end portion E2 in the first direction.

The width W1 (distance between the one end portion E1 and the other end portion E2 in the first direction) of the metal supporting layer 2 is, for example, 200 μm to 1600 μm, preferably 300 μm to 1500 μm.

A width W2 (length in the first direction) of the metal supporting layer 2 in a portion where the recessed portion 20 is formed is smaller than the width W1, and is, for example, 50 μm to 1450 μm, preferably 100 μm to 1250 μm.

### (2) First Insulating Layer

As shown in FIG. 2, the first insulating layer 3 is disposed on one side of the metal supporting layer 2 in the thickness direction of the metal supporting layer 2. The thickness direction is orthogonal to each of the first direction and the second direction. The first insulating layer 3 is disposed on one surface of the metal supporting layer 2 in the thickness direction. The first insulating layer 3 is disposed between the metal supporting layer 2 and the circuit pattern 4 in the thickness direction. That is, the first insulating layer 3 is disposed between the metal supporting layer 2 and the terminal 41A in the thickness direction. The first insulating layer 3 can insulate the metal supporting layer 2 from the circuit pattern 4. The first insulating layer 3 is made of resin. Examples of the resin include polyimide, maleimide, epoxy resin, polybenzoxazole, and polyester.

The first insulating layer 3 has a thickness T2 of, for example, 1 μm to 30 μm, preferably 3 μm to 25 μm.

As shown in FIG. 1, the first insulating layer 3 extends in the first direction and the second direction. The first insulating layer 3 has the predetermined width W11 in the first direction and extends in the second direction.

The width W11 (length in the first direction) of the first insulating layer 3 is, for example, 200 μm to 1600 μm, preferably 300 μm to 1500 μm.

### (3) Circuit Pattern

As shown in FIG. 2, the circuit pattern 4 is disposed on one side of the first insulating layer 3 in the thickness direction. In other words, the terminal 41A is disposed on one side of the metal supporting layer 2 in the thickness direction. The circuit pattern 4 is disposed on one surface of the first insulating layer 3 in the thickness direction. The circuit pattern 4 is disposed on the opposite side of the metal supporting layer 2 with respect to the first insulating layer 3 in the thickness direction. The circuit pattern 4 is made of metal. Examples of the metal include copper, silver, gold, iron, aluminum, chromium, and alloys thereof. From the viewpoint of obtaining good electrical properties, the circuit pattern 4 is preferably made of copper.

As shown in FIG. 1, the circuit pattern 4 has a plurality of terminals 41A, 41B, and a plurality of wires 42A, 42B. In other words, the wiring circuit board 1 includes a plurality of terminals 41A, 41B and a plurality of wires 42A, 42B.

The terminals 41A and 41B are aligned in the second direction. The terminal 41B is disposed away from the terminal 41A in the second direction. The terminals 41A and 41B each extend in the first and second directions. Each of the terminals 41A and 41B has a square land shape. One end portion of each of the terminals 41A and 41B in the first direction overlaps the recessed portion 20 of the metal supporting layer 2 in the thickness direction.

The terminals 41A and 41B each have a width W21 (length in the first direction) of, for example, 100 μm to 1400 μm, preferably 200 μm to 1300 μm.

When the width W11 of the first insulating layer 3 is 100%, the width W21 of each of the terminals 41A and 41B is, for example, 50% to 95%, preferably 65% to 90%.

When the width W0 of the wiring circuit board 1 is 100%, the width W21 of each of the terminals 41A and 41B is, for example, 50% to 95%, preferably 65% to 90%.

The wire 42A is connected to the other end portion of the terminal 41A 1 in the first direction. The wire 42B is connected to the other end portion of the terminal 41B in the first direction. The wire 42B is disposed away from the wire 42B.

### (4) Second Insulating Layer

As shown in FIG. 2, the second insulating layer 5 is disposed on one side of the first insulating layer 3 in the thickness direction. The second insulating layer 5 is disposed on one surface of the first insulating layer 3 in the thickness direction. The second insulating layer 5 is made of resin. Examples of the resin include polyimide, maleimide, epoxy resin, polybenzoxazole, and polyester.

As shown in FIG. 1, the second insulating layer 5 covers the wires 42A and 42B. The second insulating layer 5 may cover the peripheral portion of each of the terminals 41A and 41B. The second insulating layer 5 does not cover the center portion of each of the terminals 41A and 41B.

### 2. Positional Relationship of Metal Supporting Layer, First Insulating Layer, Circuit Pattern, and Second Insulating Layer

Next, the positional relationship of the metal supporting layer 2, the first insulating layer 3, the circuit pattern 4, and the second insulating layer 5 will be described in detail.

As shown in FIG. 1, the first insulating layer 3 has a first end edge E11 and a second end edge E12.

The first end edge E11 is disposed at one end portion of the first insulating layer 3 in the first direction. The first end edge E11 is an end edge on one side of the first insulating layer 3 in the first direction. The first end edge E11 extends in the second direction. In other words, the first end edge E11 extends in a direction in which the plurality of terminals 41A, 41B are aligned.

The second end edge E12 is disposed on the side opposite to the first end edge E11 in the first direction. The second end edge E12 is disposed at the other end portion of the first insulating layer 3 in the first direction. The second end edge E12 is an end edge on the other side of the first insulating layer 3 in the first direction. The second end edge E12 is disposed away from the first end edge E11 in the first direction. The second end edge E12 extends in the second direction.

The terminal 41A has a third end edge E13 and a fourth end edge E14.

The third end edge E13 is disposed at one end portion of the terminal 41A in the first direction. The third end edge E13 is an end edge on one side of the terminal 41A in the first direction. The third end edge E13 is disposed between the first end edge E11 and the second end edge E12 in the first direction. The third end edge E13 is disposed between the first end edge E11 and the fourth end edge E14 in the first direction. The third end edge E13 overlaps the recessed portion 20 in the thickness direction. In other words, the recessed portion 20 overlaps the third end edge E13 in the thickness direction. The third end edge E13 extends in the second direction. The third end edge E13 is disposed away from the first end edge E11 in the first direction.

A distance D1 between the first end edge E11 and the third end edge E13 is, for example, 200 μm or less, preferably 100 μm or less, more preferably 75 μm or less, more preferably 50 μm or less. The distance D1 between the first end edge E11 and the third end edge E13 may be 30 μm or less, or 15 μm or less. When the distance D1 between the first end edge E11 and the third end edge E13 is the above-described upper limit or less, the first end edge E11 of the first insulating layer 3 can be brought closer to the terminal 41A to reduce the size of the wiring circuit board 1. The distance D1 between the first end edge E11 and the third end edge E13 may be shorter than the width W21 of each of the terminals 41A and 41B.

The distance D1 between the first end edge E11 and the third end edge E13 is, for example, 5 μm or more, preferably 10 μm or more.

The fourth end edge E14 is disposed at the other end portion of the terminal 41A in the first direction. The fourth end edge E14 is an end edge on the other side of the terminal 41A in the first direction. The fourth end edge E14 is disposed away from the third end edge E13 in the first direction. The fourth end edge E14 is disposed between the third end edge E13 and the second end edge E12 in the first direction. The fourth end edge E14 is disposed away from the second end edge E12 in the first direction. The wires 42A and 42B are disposed between the second end edge E12 and the fourth end edge E14 in the first direction. The wires 42A and 42B extend between the second end edge E12 and the fourth end edge E14 in the second direction. The fourth end edge E14 extends in the second direction.

A distance D3 between the second end edge E12 and the fourth end edge E14 is, for example, 200 μm or less, preferably 150 μm or less. The distance D3 between the second end edge E12 and the fourth end edge E14 is, for example, 10 μm or more, preferably 25 μm or more. The distance D3 between the second end edge E12 and the fourth end edge E14 may be longer than the distance D1 between the first end edge E11 and the third end edge E13. The distance D3 between the second end edge E12 and the fourth end edge E14 may be shorter than the width W21 of each of the terminals 41A and 41B.

The metal supporting layer 2 has a fifth end edge E15 and a sixth end edge E16.

The fifth end edge E15 is disposed at the one end portion E1 of the metal supporting layer 2 in the first direction. In the present embodiment, the fifth end edge E15 is the bottom of the recessed portion 20. In the portion where the recessed portion 20 is formed, the fifth end edge E15 is an end edge on one side of the metal supporting layer 2 in the first direction. The fifth end edge E15 overlaps the terminal 41A in the thickness direction. The fifth end edge E15 is disposed between the first end edge E11 and the second end edge E12 in the first direction. The fifth end edge E15 is disposed between the first end edge E11 and the sixth end edge E16 in the first direction. The fifth end edge E15 is disposed between the third end edge E13 and the sixth end edge E16 in the first direction. The fifth end edge E15 is disposed between the third end edge E13 and the fourth end edge E14 in the first direction. The fifth end edge E15 extends in the second direction. The fifth end edge E15 is disposed away from the first end edge E11 in the first direction.

In the present embodiment, a distance D2 between the first end edge E11 and the fifth end edge E15 may be longer than the distance D1 between the first end edge E11 and the third end edge E13. The distance D2 between the first end edge E11 and the fifth end edge E15 is, for example, 10 μm to 300 μm, preferably 10 μm to 200 μm, more preferably 20 μm to 100 μm.

A total sum of the distance D1 between the first end edge E11 and the third end edge E13 and the distance D2 between the first end edge E11 and the fifth end edge E15 is 15 μm or more, preferably 30 μm or more. When the total sum of the distances D1 and D2 is the above-described lower limit or more, a distance from the terminal 41A to the metal supporting layer 2 can be secured while bringing the first end edge E11 of the first insulating layer 3 closer to the terminal 41A. Therefore, even though the solder on the terminal 41A flows toward the first end edge E11, it is possible to suppress a short circuit between the terminal 41A and the metal supporting layer 2 due to the flowing solder.

The upper limit of the total sum of the distances D1 and D2 is not limited as long as the rigidity of the metal supporting layer 2 is not excessively lowered. The total sum of the distances D1 and D2 is, for example, 500 μm or less, preferably 300 μm or less, more preferably 150 μm or less.

The sixth end edge E16 is disposed at the other end portion of the metal supporting layer 2 in the first direction. The sixth end edge E16 is an end edge on the other side of the metal supporting layer 2 in the first direction. The sixth end edge E16 is disposed on the opposite side of the first end edge E11 with respect to the fifth end edge E15 in the first direction. The sixth end edge E16 is disposed away from the fifth end edge E15 in the first direction. In the present embodiment, the sixth end edge E16 is disposed between the fifth end edge E15 and the second end edge E12 in the first direction. The sixth end edge E16 may be disposed on the other side from the second end edge E12 in the first direction. In other words, the sixth end edge E16 may be disposed on the opposite side of the fifth end edge E15 with respect to the second end edge E12 in the first direction. The sixth end edge E16 extends in the second direction.

As shown in FIG. 2, a portion of the second insulating layer 5 is disposed between the first end edge E11 and the third end edge E13 in the first direction. Thus, it is possible to suppress flowing of the solder on the terminal 41A toward the first end edge E11. In the present embodiment, the second insulating layer 5 covers the third end edge E13. In this manner, it is possible to further suppress flowing of the solder on the terminal 41A toward the first end edge E11.

### 3. Operations and Effects

(1) According to the wiring circuit board 1, as shown in FIG. 1, the total sum of the distance D1 between the first end edge E11 and the third end edge E13 and the distance D2 between the first end edge E11 and the fifth end edge E15 of the metal supporting layer 2 is 15 μm or more.

Therefore, even when the first end edge E11 of the first insulating layer 3 is disposed close to the terminal 41A, the distance from the terminal 41A to the metal supporting layer 2 can be secured.

Therefore, even though the solder on the terminal 41A flows toward the first end edge E11, it is possible to suppress a short circuit between the terminal 41A and the metal supporting layer 2 due to the flowing solder.

As a result, the wiring circuit board 1 can suppress a short circuit between the terminal 41A and the metal supporting layer 2 while achieving reduction in the size of the wiring circuit board 1.

(2) According to the wiring circuit board 1, the distance D1 (cf. FIG. 1) between the first end edge E11 and the third end edge E13 is 200 μm or less.

Therefore, it is possible to achieve reduction in the size of the wiring circuit board.

(3) According to the wiring circuit board 1, as shown in FIG. 1, the distance D2 between the first end edge E11 and the fifth end edge E15 is longer than the distance D1 between the first end edge E11 and the third end edge E13.

Therefore, the first end edge E11 of the first insulating layer 3 can be brought closer to the terminal 41A.

As a result, it is possible to achieve further reduction in the size of the wiring circuit board 1.

(4) According to the wiring circuit board 1, as shown in FIG. 2, a portion of the second insulating layer 5 is disposed between the first end edge E11 and the third end edge E13 in the first direction.

Therefore, the second insulating layer 5 between the first end edge E11 and the third end edge E13 can suppress flowing of the solder on the terminal 41A toward the first end edge E11.

(5) According to the wiring circuit board 1, as shown in FIG. 2, the second insulating layer 5 covers the third end edge E13.

Therefore, the second insulating layer 5 can further suppress flowing of the solder on the terminal 41A toward the first end edge E11.

### 4. Modification

A modification will be described. In the modification, the same reference numerals are provided for the same members as those in the above-described embodiment, and the description thereof is omitted.

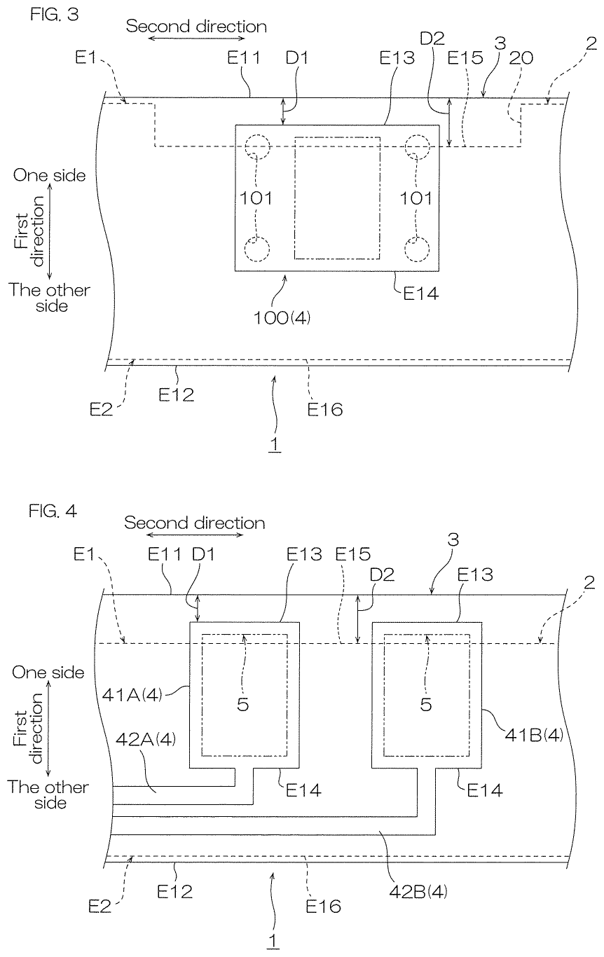

(1) As shown in FIG. 3, the wiring circuit board 1 may include a ground terminal 100 that is not connected to a wire. The ground terminal 100 has a via hole 101 that penetrates through the first insulating layer 3. The ground terminal 100 is electrically connected to the metal supporting layer 2 in the via hole 101.

(2) As shown in FIG. 4, the metal supporting layer 2 may not have the recessed portion 20.

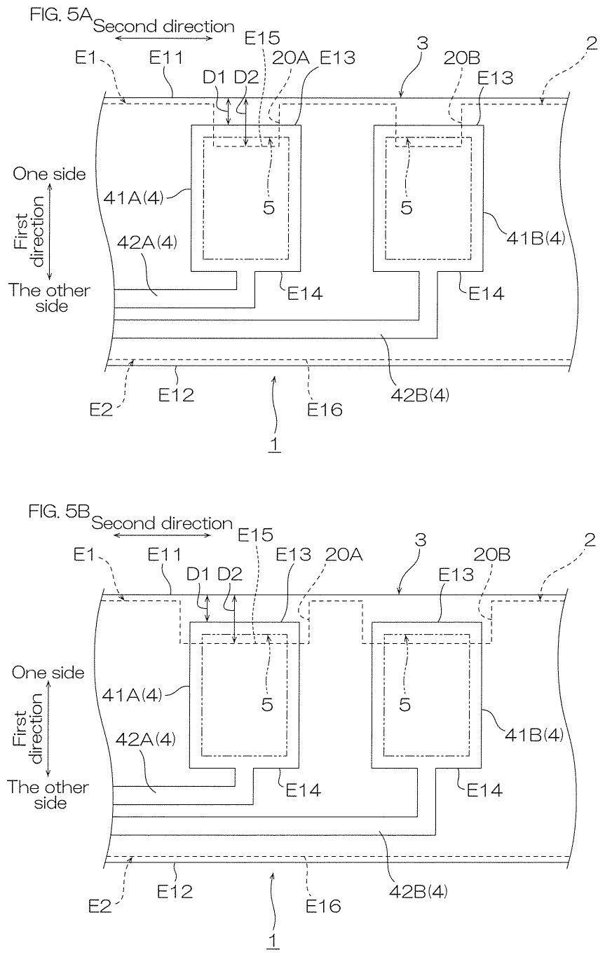

(3) As shown in FIGS. 5A and 5B, the metal supporting layer 2 may have a recessed portion 20A that overlaps the terminal 41A and a recessed portion 20B that overlaps the terminal 41B. As shown in FIG. 5A, in the second direction, the length of the recessed portion 20A may be shorter than the length of the terminal 41A. As shown in FIG. 5B in the second direction, the length of the recessed portion 20A may be longer than the length of the terminal 41A.

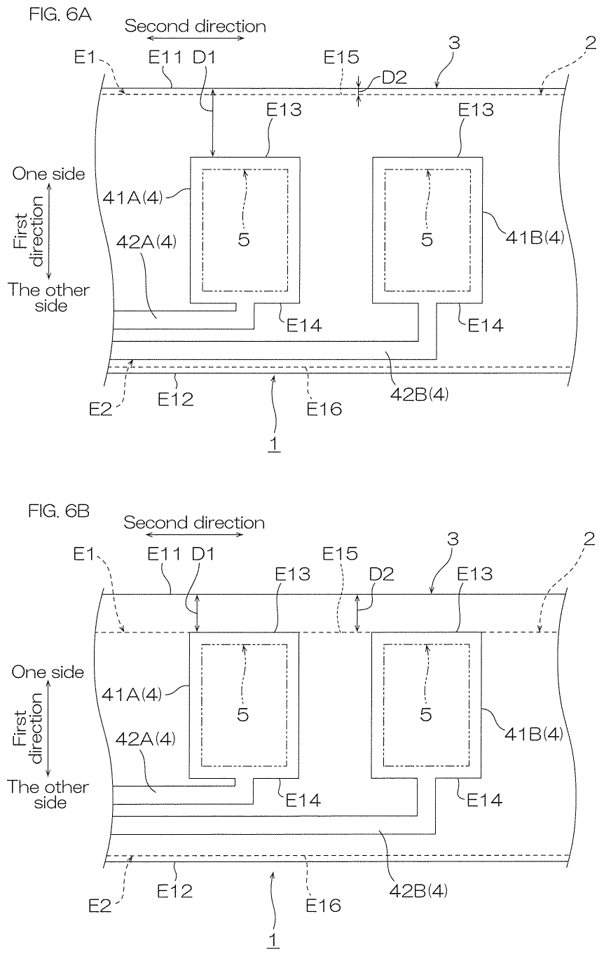

(4) As shown in FIGS. 6A and 6B, the distance D2 between the first end edge E11 and the fifth end edge E15 may not be longer than the distance D1 between the first end edge E11 and the third end edge E13. As shown in FIG. 6A, the distance D2 may be shorter than the distance D1. As shown in FIG. 6B, the distance D2 may be the same as the distance D1.

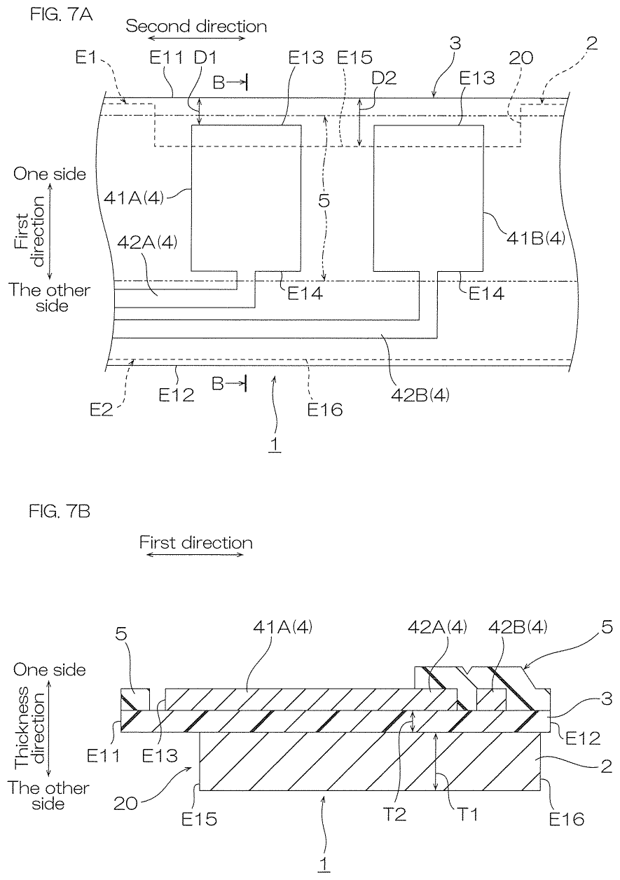

(5) As shown in FIGS. 7A and 7B, the second insulating layer 5 may not cover the peripheral portion of the terminal 41A.

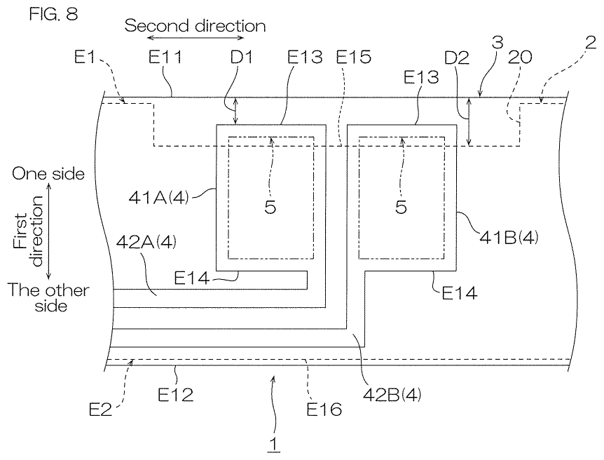

(6) As shown in FIG. 8, each of the wires 42A and 42B may be a signal line for transmitting electrical signals. The wires 42A and 42B may constitute a differential pair. The wire 42B is spaced apart at a predetermined interval from the wire 42A and extends in parallel to the wire 42A. The length of the wire 42B is preferably the same as that of the wire 42A.

(7) The modifications (1) to (6) can also achieve the same operations and effects as that of the above-described embodiment.

While the illustrative embodiments of the present invention are provided in the above description, such is for illustrative purpose only and it is not to be construed restrictively. Modification and variation of the present invention that will be obvious to those skilled in the art is to be covered by the following claims.

### INDUSTRIAL APPLICABILITY

The wiring circuit board of the present invention can be used to connect to electronic components.

### DESCRIPTION OF REFERENCE NUMERALS

1 wiring circuit board
2 metal supporting layer
3 first insulating layer
41A terminal
42A wire
5 second insulating layer
20 recessed portion
E1 one end portion of metal supporting layer
E2 the other end portion of metal supporting layer
E11 first end edge
E12 second end edge
E13 third end edge
E14 fourth end edge
E15 fifth end edge
E16 sixth end edge
D1 distance
D2 distance
20A recessed portion
20B recessed portion

1. A wiring circuit board comprising:
a metal supporting layer;
a terminal disposed on one side of the metal supporting layer in a thickness direction of the metal supporting layer; and
a first insulating layer disposed between the metal supporting layer and the terminal in the thickness direction,
the first insulating layer extending in a first direction orthogonal to the thickness direction, and in the first direction, having a first end edge and a second end edge disposed on a side opposite to the first end edge,
the terminal having a third end edge disposed between the first end edge and the second end edge in the first direction, and a fourth end edge disposed between the third end edge and the second end edge in the first direction,
the metal supporting layer having a fifth end edge disposed between the first end edge and the second end edge in the first direction, and a sixth end edge disposed on the side opposite to the first end edge with respect to the fifth end edge in the first direction,
wherein a total sum of a distance between the first end edge and the third end edge and a distance between the first end edge and the fifth end edge is 15 μm or more.

2. The wiring circuit board according to claim 1, wherein the distance between the first end edge and the third end edge is 200 μm or less.

3. The wiring circuit board according to claim 1, wherein the distance between the first end edge and the fifth end edge is longer than the distance between the first end edge and the third end edge.

4. The wiring circuit board according to claim 1, further comprising a second insulating layer disposed on one side of the first insulating layer in the thickness direction,
wherein a portion of the second insulating layer is disposed between the first end edge and the third end edge in the first direction.

5. The wiring circuit board according to claim 4, wherein the second insulating layer covers the third end edge.

6. The wiring circuit board according to claim 1, wherein the metal supporting layer has one end portion and the other end portion in the first direction, and has a recessed portion recessed from the one end portion toward the other end portion in the first direction,
the recessed portion overlaps the third end edge in the thickness direction, and
the fifth end edge is a bottom of the recessed portion.

7. The wiring circuit board according to claim 1, further comprising a wire disposed between the second end edge and the fourth end edge and connected to the terminal.
